(19) United States
(12) Patent Application Publication
(10) Pub. No.: US 2023/0155078 A1
(43) Pub. Date: May 18, 2023

(54) COMPUTING DEVICES WITH UNDER-DISPLAY SENSORS

(71) Applicant: Saphlux, Inc., Branford, CT (US)

(72) Inventors: Chen Chen, Branford, CT (US); Jie Song, Branford, CT (US)

(73) Assignee: Saphlux, Inc., Branford, CT (US)

(21) Appl. No.: 18/151,201

(22) Filed: Jan. 6, 2023

Related U.S. Application Data
(63) Continuation of application No. PCT/US21/40477, filed on Jul. 6, 2021.
(60) Provisional application No. 63/048,232, filed on Jul. 6, 2020.

(51) Int. Cl. H01L 33/50; H01L 25/16; G09G 3/32; G06F 3/042

(52) U.S. Cl. CPC H01L 33/505; H01L 25/167; G09G 3/32; G06F 3/0421; H01L 33/502; G09G 2360/144; G09G 2320/0626; G09G 2354/00; G06V 40/1318

(57) ABSTRACT

In accordance with some embodiments of the present disclosure, a computing device is provided. The computing device may include a display device and one or more sensors positioned beneath the display device. The one or more sensors may be configured to detect light passed through a display area of the display device. The display area of the display device may include a plurality of semiconductor devices for emitting light. The sensors may be positioned beneath the display area of the display device. In some embodiments, the sensors may further generate sensing data based on the detected light. The computing device may perform one or more operations based on the sensing data, such as adjusting a brightness of the display device, turning on or off the display device, locking or unlocking a screen of the computing device, performing one or more operations using an application running on the computing device, etc.

### CROSS-REFERENCE TO RELATED APPLICATIONS

This application is a continuation of International Patent Application No. PCT/US21/40477, filed Jul. 6, 2021, which claims the benefits of U.S. Provisional Patent Application No. 63/048,232, entitled “Computing Devices with Under-Display Sensors,” filed Jul. 6, 2020, each of which is incorporated herein by reference in its entirety.

### TECHNICAL FIELD

The implementations of the disclosure relate generally to computing devices and, more specifically, to computing devices with under-display sensors and methods of manufacturing the same.

### BACKGROUND

Mobile devices, such as mobile phones and wearable computers, may utilize sensors to implement various applications. For example, a mobile phone may include an infrared (IR) sensor for detecting ambient light in the surroundings of the mobile device. However, IR signals and other optical signals cannot penetrate displays of conventional mobile devices (e.g., displays including light-emitting diodes (LEDs) comprising Gallium Arsenide and/or other material that may block the IR signals). As a result, an IR sensor may have to be positioned on top of a display of a conventional mobile device and/or in a non-display area of the display (e.g., an area of the display that does not include LEDs). This may limit the screen-to-body ratio of the mobile device and may prevent incorporation of sensors into mobile devices of small screens.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In accordance with one or more aspects of the present disclosure, a computing device is provided. The computing device includes: a display device and a sensor positioned beneath the display device. In some embodiments, a display area of the display device comprises a plurality of semiconductor devices for emitting light. The sensor is to detect a signal passed through the display area of the display device.

In some embodiments, the sensor is positioned beneath the display area of the display device.

In some embodiments, the sensor is further to generate sensing data based on the detected signal.

In some embodiments, the detected signal may include an optical signal passed through the display area of the display device.

In some embodiments, the detected signal includes light passed through the display area of the display device.

In some embodiments, the sensing data represents an amount of light reflected by an object.

In some embodiments, the object is located on a surface of the display device, and wherein the sensor is located beneath the surface of the display device.

In some embodiments, the sensing data represents an amount of ambient light in the computing device's surroundings. In some embodiments, the sensing data corresponds to an optical signal passed through the display area of the display device.

In some embodiments, the computer device is to perform one or more operations based on the sensing data, wherein the one or more operations include at least one of adjusting a brightness of the display device, turning on the display device, turning off the display device, locking a screen of the computing device, unlocking the screen of the computing device, performing one or more operations using an application running on the computing device.

In some embodiments, the computer device further includes a processing device to generate one or more control signals that instruct the computing device to perform the one or more operations.

In some embodiments, the plurality of semiconductor devices includes a first plurality of semiconductor devices for emitting first light of a first color, a second plurality of semiconductor devices for emitting second light of a second color, and a third plurality of semiconductor devices for emitting third light of a third color, wherein the first plurality of semiconductor devices includes a first plurality of quantum dots placed in one or more first nanoporous structures, and wherein the second plurality of semiconductor devices includes a second plurality of quantum dots placed in one or more second nanoporous structures.

In some embodiments, the sensor is positioned beneath the plurality of the semiconductor devices.

In some embodiments, the sensor transmits an optical signal that passes through the display device of the computer device.

In accordance with one or more aspects of the present disclosure, a method is provided. The method includes: detecting, using one or more sensors positioned beneath a display device of a computing device, a signal that passed through a display area of the display device, wherein the display area of the display device comprises a plurality of semiconductor devices for emitting light; generating sensing data based on the detected light; and performing, by the computing device, one or more operations based on the sensing data.

In some embodiments, the signal comprises light.

In some embodiments, the signal comprises an optical signal.

In some embodiments, the sensing data represents an amount of ambient light in the computing device's surrounding. In some embodiments, the sensing data represents an amount of light reflected by an object located on top of the display device of the computing device.

In some embodiments, the object is located on a surface of the display device, and wherein the one or more sensors are positioned beneath the surface of the display device.

In some embodiments, the sensing data corresponds to an optical signal passed through the display area of the display device.

In some embodiments, the method further includes receiving, using the one or more sensors positioned beneath the display area, the optical signal passed through the display area of the display device.

In some embodiments, the method further includes transmitting, receiving, using the one or more sensors positioned beneath the display area, the optical signal passed through the display area of the display device.

In some embodiments, the one or more operations include at least one of adjusting a display property of the display of the computing device, performing one or more operations using an application running on the computing device, unlocking a screen of the computing device, locking the screen of the computing device, or displaying content relating to biometric information of a user.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIGS. 1A-1B are block diagrams depicting an example of a computing device in accordance with some embodiments of the present disclosure.

FIG. 1C depicts an example of a display area of a display in accordance with some embodiments of the present disclosure.

FIG. 2 is a block diagram illustrating an example mechanism for implementing an under-display sensor in accordance with some embodiments of the present disclosure.

FIG. 3 is a block diagram illustrating an example of a semiconductor device in accordance with some embodiments of the present disclosure.

FIG. 4 is a block diagram illustrating an example of a light-emitting structure in accordance with some embodiments of the present disclosure.

FIGS. 5A, 5B, and 5C are block diagrams illustrating structures associated with an example process for fabricating a light conversion device in accordance with some embodiments of the present disclosure.

FIG. 6 is a diagram illustrating example emission spectra of light that can transmit through a display device in accordance with some embodiments of the present disclosure.

FIG. 7 is a flowchart illustrates an example process for implementing a computing device in accordance with some embodiments of the present disclosure.

FIG. 8 is a block diagram depicting an example of a computer system in accordance with some embodiments of the present disclosure.

### DETAILED DESCRIPTION

In accordance with one or more aspects of the present disclosure, computing devices with under-display sensors are provided. The computing device may be and/or include a mobile phone, a laptop, a desktop, a tablet computer device, a wearable computing device (e.g., watches, eyeglasses, contact lenses, head-mounted displays, virtual reality headsets, activity trackers, clothing, wrist bands, skin patches, etc.), a television, etc. As referred to herein, a sensor may be and/or include a device that can measure one or more physical parameters, chemical parameters, biological parameters, environmental parameters, and/or the like. Examples of the sensor may include an image sensor, a chemical sensor, a biosensor, etc.

As an example, a computing device in accordance with the present disclosure may include a display and one or more sensors positioned beneath the display. The display may include a display area that may emit light. The display area may include a plurality of semiconductor devices that may emit light (e.g., semiconductor devices emitting red light, green light, and blue light). The display may enable certain light and/or optical signals to pass through the display area and/or the semiconductor devices.

The sensors may be positioned beneath the display area of the display and may detect input signals (e.g., light, optical signals, etc.) that can penetrate and/or pass through the display and/or the display area of the display. The sensors may also generate sensing data based on the detected light and/or input signals. The sensors may also transmit optical signals that may pass through the display and/or the display area of the display to facilitate communications with one or more other computing devices. As will be described in greater detail below, the computing device may implement various applications (e.g., imaging applications, proximity detection, ambient light detection, user identification, motion and/or object detection, wireless communications, biometric and/or fitness applications, medical applications, etc.) using the sensors.

Examples of embodiments of the present disclosure will be described in more detail with reference to the accompanying drawings. It should be understood that the following embodiments are given by way of illustration only to provide thorough understanding of the disclosure to those skilled in the art. Therefore, the present disclosure is not limited to the following embodiments and may be embodied in different ways. Further, it should be noted that the drawings are not to precise scale and some of the dimensions, such as width, length, thickness, and the like, can be exaggerated for clarity of description in the drawings. Like components are denoted by like reference numerals throughout the specification.

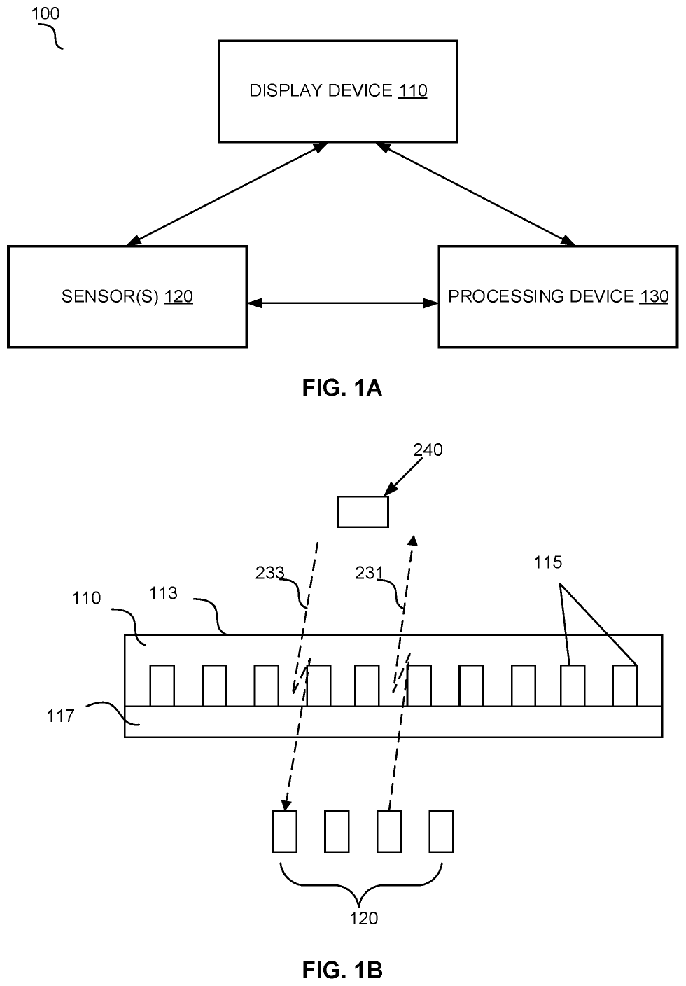

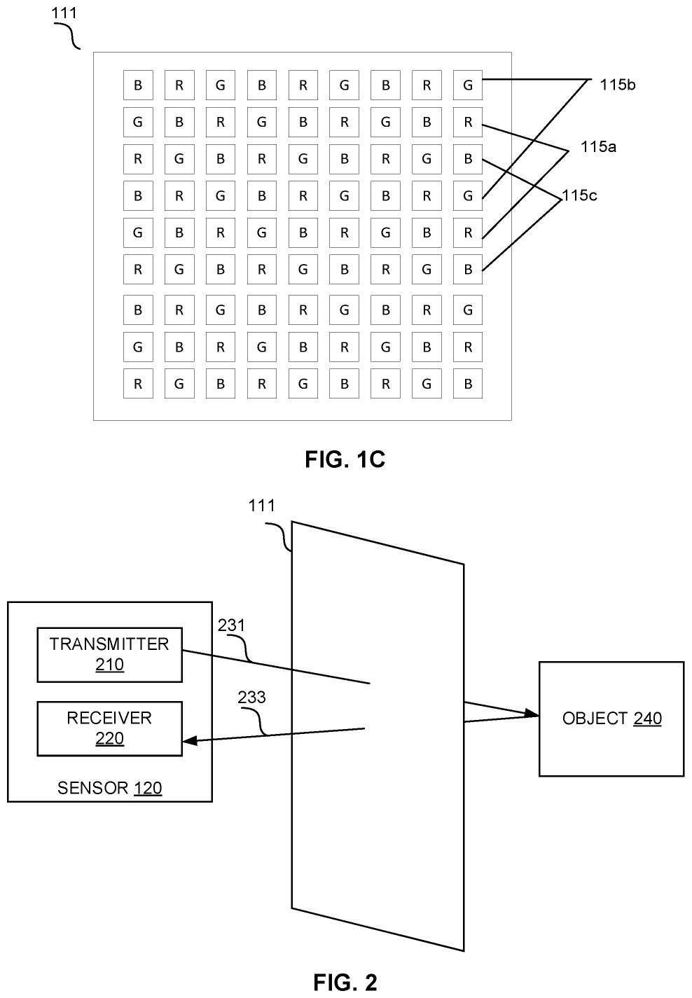

FIG. 1A is a block diagram depicting an example 100 of a computing device in accordance with some embodiments of the present disclosure. The computing device may be and/or include one or more mobile phones, laptops, desktops, tablet computer devices, wearable computing devices (e.g., watches, eyeglasses, contact lenses, head-mounted displays, virtual reality headsets, activity trackers, clothing, wrist bands, skin patches, etc.), televisions, etc.

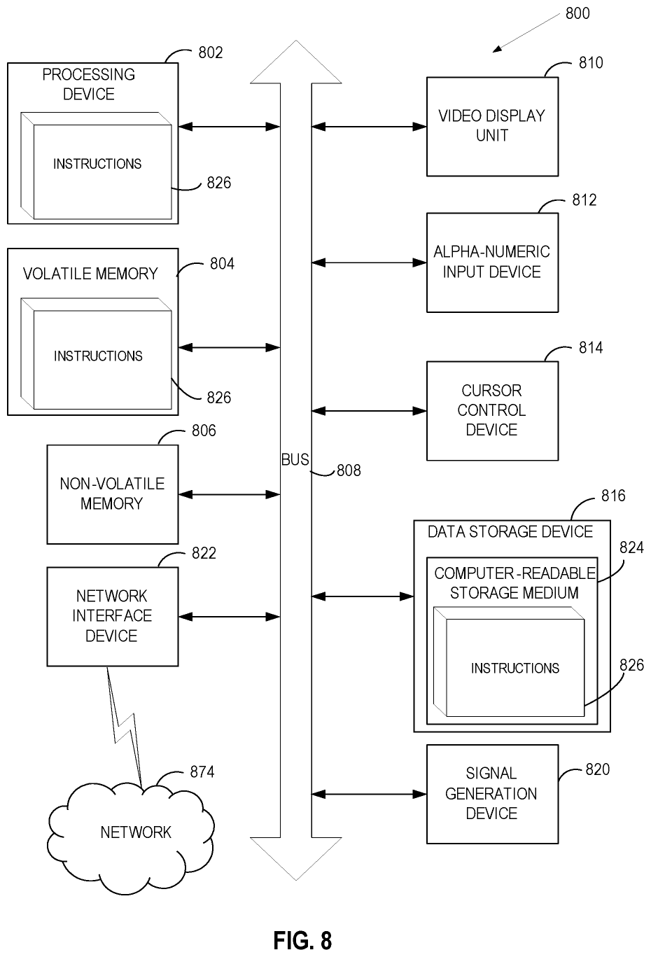

As illustrated, the computing device 100 may include a display device 110, one or more sensors 120, and a processing device 130. The computing device 100 may also include any other suitable component for implementing the embodiments of the present disclosure. In some embodiments, the computing device 100 may be and/or include a computing system and/or one or more components of the computer system as described in connection with FIG. 8.

The display device 110 may include a display area comprising a plurality of semiconductor devices that may emit light (e.g., the display area 111 of FIG. 1C). The semiconductor devices may emit light of various colors. For example, a first set of the micro semiconductor devices may emit light of a first color (also referred to as the “first plurality of semiconductor devices”). A second set of the micro semiconductor devices may emit light of a second color (also referred to as the “second plurality of semiconductor devices”). A third set of the semiconductor devices may emit light of a third color (also referred to as the “third plurality of semiconductor devices”). As an example, the first color, the second color, and the third color may be a red color, a green color, and a blue color, respectively. In some embodiments, the display device 110 and/or the display area of the display device 110 may include one or more components as described in connection with FIGS. 1B and 1C below. In some embodiments, the display device 110 may further include a non-display area that does not emit light (e.g., an area that does not include light-emitting devices). In some embodiments, the display device 110 does not include a non-display area. As such, the display device 110 may be used to implement full-screen applications. In some embodiments, the display device 110 may be a flexible and/or foldable display.

Each of the semiconductor devices may include a light-emitting structure for producing light. The light-emitting structure may include one or more layers of semiconductive materials and/or any other suitable material for producing light. For example, the light-emitting structure may include one or more epitaxial layers of a group III-V material (e.g., GaN), one or more quantum well structures, etc. In some embodiments, the light-emitting structure may include one or more components as described in conjunction with FIG. 4.

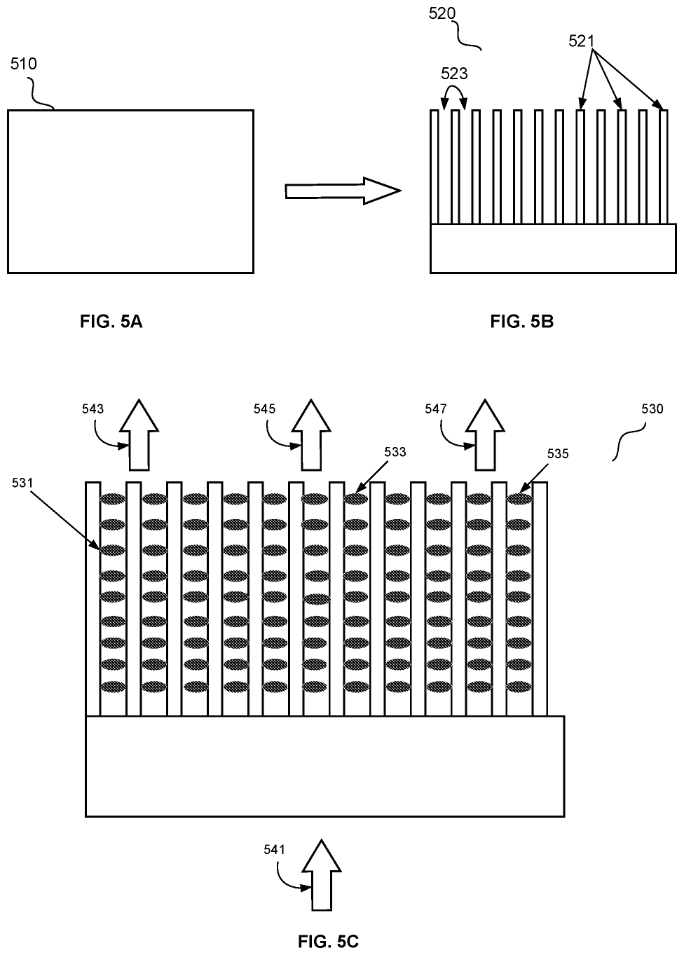

One or more of the semiconductor devices may include a light-conversion device that may convert input light of a first color (e.g., light produced by one or more light-emitting structures) into output light of a second color (e.g., a color that is different from the first color). The light-conversion device may comprise quantum dots placed in one or more nanoporous structures. When excited by electricity or light, each of the quantum dots may emit light of a certain wavelength and/or a range of wavelengths. For example, the first plurality of semiconductor devices may include first QDs with a first emission wavelength (QDs that can convert input light to red light). The second plurality of semiconductor devices may include second QDs with a second emission wavelength (QDs that can convert input light to green light). The third plurality of semiconductor devices may include third QDs with a third emission wavelength (QDs that can convert input light to blue light). The first QDs, the second QDs, and/or the third QDs may be placed in one or more nanoporous structures as described herein. In some embodiments, the third plurality of micro semiconductor devices do not include QDs. In some embodiments, each of the semiconductor devices may include a light-conversion device as described in connection with FIGS. 5A-5C below.

In some embodiments, the semiconductor devices of the display area 111 may include monolithic light-emitting devices that can produce light of a certain color (e.g., blue LEDs). The display device 110 and/or the display area 111 may further include one or more light conversion devices (a light-conversion device as described in connection with FIGS. 5A-5C below) attached to the light-emitting devices to emit light of various colors.

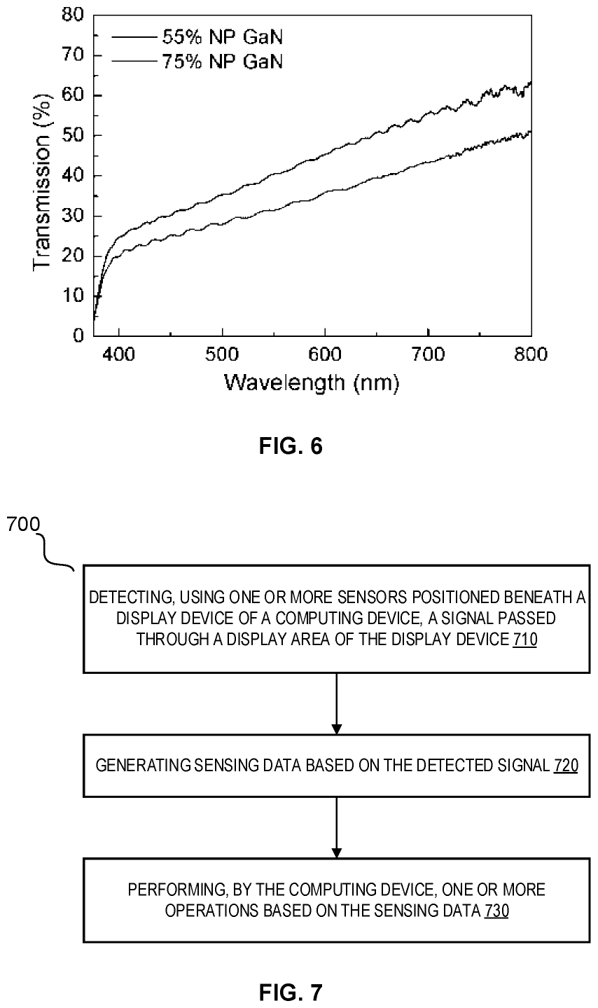

As shown in FIG. 6, light of certain wavelengths may penetrate and/or transmit through the semiconductor devices and the display area of the display device. As such, a sensor may be positioned beneath the display area and/or the semiconductor devices to detect light and/or optical signals that penetrates the display area.

Computing device 100 may further include one or more sensors 120 configured to detect signals for measuring one or more physical parameters, chemical parameters, biological parameters, environmental parameters, and/or the like. The input may include, for example, light, an optical signal, etc. In some embodiments, sensor 120 may be and/or include an image sensor that can detect signals and/or information that may be used to generate an image. In some embodiments, sensor 120 may detect light and may generate an output signal indicating an amount of the detected light (e.g., an intensity of the detected light), a wavelength of the detected light, and/or any other suitable feature of the detected light. As will be described in further detail below, the detected light may correspond to ambient light emitted from the surroundings of the display device 110 and/or the computing device 100, light reflected from a surface of an object, etc. Sensor 120 may include a receiver that can detect light and/or optical signals that can transmit through the display area 111 and/or a transmitter that can transmit light and/or optical signals that can transmit through the display area 111. In some embodiments, sensor 120 may be and/or include a sensor described in connection with FIG. 2 below.

In some embodiments, one or more sensors 120 may be and/or include an infrared (IR) sensor that may emit and/or detect IR radiation. As referred to herein, IR radiation or IR light may include electromagnetic radiation with wavelengths between about 700 nm and about 1 mm. In some embodiments, a sensor 120 may include a receiver that can detect IR radiation and/or IR signals, a transmitter that can generate and/or transmit IR radiation and/or IR signals, etc. In some embodiments, a sensor 120 does not have to include a transmitter.

In some embodiments, sensors 120 may include one or more sensors that may measure biometric parameters of a user. The biometric parameters may include, for example, a heart rate, a blood pressure, a respiration rate, an amount of oxygen consumption, a glucose level (e.g., a tear glucose level, a blook glucose level, etc.), an eye pressure and/or intraocular pressure, etc. As an example, computing device 100 may include a contact lenses with embedded sensors 120 for measuring a tear glucose level, an intraocular pressure, etc. of the user. As another example, computing device 100 may include a flexible display that may be attached to one or more portions of the body of the user to measure biometric parameters of the user.

Sensors 120 may be arranged in any suitable manner to detect light and/or optical signals in accordance with various embodiments of the present disclosure. In some embodiments, as illustrated in FIG. 1B, one or more sensors 120 may be positioned beneath the display area 111 of the display device 110. The sensors 120 may transmit and/or detect light and/or optical signals that may pass through the display area 111. The detected light may correspond to ambient light in the surroundings of the computing device, light reflected by an object, etc. The detected optical signals may be and/or include signals that are carried using light (e.g., visible light, infrared (IR) light, ultraviolet (UV) light, etc.). The optical signals may be generated by emitting light using one or more light emitting diodes and/or any other suitable devices that can emit light, modulating, pulsing, encoding, etc. the light, etc.

The sensor 120 may also generate an output signal representative of the detected light and/or optical signals (e.g., light and/or optical signals passed through the display area 111 of the display device 110). For example, the sensor 120 may generate the output signal by generating an electrical signal (e.g., a current signal, a voltage signal, etc.) indicative of an amount of the detected light (e.g., an intensity of the detected light) at one or more particular time instants and/or over time, the emission spectra of the detected light, etc. The electrical signal may be an analog signal, a digital signal, etc. As another example, the sensor 120 may generate the output signal by demodulating a detected optical signal, decoding the detected optical signal, and/or processing the detected optical signal in any other suitable manner. In some embodiments, the output signal generated by the sensors 120 may be and/or include the detected optical signal.

In some embodiments, the sensor 120 may generate and/or send optical signals to facilitate wireless communications between the computing device 100 and one or more other devices. For example, the sensor 120 may generate an optical signal for transmission of data and/or information by modulating, pulsing, encoding, etc. light produced by the sensor 120 and/or any other suitable device that can emit light. The optical signal may transmit through the display area 111 (e.g., penetrate the display area 111 and the semiconductor devices of the display area 111 that produce light). The optical signal that passed through the display area 111 may be received by another computing device (e.g., via a receiver that can receive the optical signal) and may then be processed (e.g., demodulating, decoding, etc.). Sensor(s) 120 may be used for Li-Fi (light fidelity) applications, remote control applications, and/or any other application utilizing optical wireless communications and/or light wireless communications.

In some embodiments, the computing device 100 may include multiple sensors 120 that are arranged in one or more arrays (e.g., one or more rows and/or columns) and/or in any other suitable manner. Each of the sensors 120 may sense light and generate an output signal as described above. As such, sensors 120 that are disposed in different locations may detect light with respect to various regions of the computing device and/or display device.

As illustrated in FIG. 1A, computing device 100 may also include a processing device 130. The processing device 130 may be and/or include one or more general-purpose processing devices such as a microprocessor, central processing unit, or the like. For example, the processing device 130 may be and/or include a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device 130 may also be one or more special-purpose processing devices such as an application specific integrated circuit (ASIC), a field programmable gate array (FPGA), a digital signal processor (DSP), network processor, or the like. The processing device 130 may be configured to execute instructions for performing the operations and steps discussed herein. In one implementation, the processing device 130 may be integrated with the computing device 100. In another implementation, the processing device 130 and the computing device 100 may be implemented as individual devices.

The processing device 130 may receive sensing data from one or more of the sensors 120. The sensing data may include one or more output signals generated by one or more sensors 120 as described herein. As an example, one or more of the output signals may indicate an amount of light detected by a respective sensor 120 at a particular moment and/or a period of time, a change in the amount of the light and/or input during a period of time, values of light and/or other input detected by the sensors 120 over time, etc. As another example, one or more of the output signals may correspond to an optical signal received by one or more sensors 120.

The processing device 130 may cause the computing device 100 to perform one or more operations based on the sensing data (e.g., by generating one or more control signals that instruct the computing device to perform the one or more operations). Examples of the operations may include adjusting a brightness and/or any other display property of the computing device (e.g., brightening or dimming the display device 110, turning on or turning off the display device 110, etc.), unlocking a screen of the computing device, locking the screen of the computing device, running an application on the computing device, performing one or more operations using the application (e.g., making a call, sending a message, generating and/or displaying media content, making a payment, etc.), displaying content on the display device, stop running the application on the computing device, etc. In some embodiments, performing the operation(s) may involve displaying content relating to biometric information of a user. The biometric information may include one or more biometric parameters, such as a heart rate, a blood pressure, a respiration rate, an amount of oxygen consumption, a glucose level, an eye pressure and/or intraocular pressure, etc. The biometric information may also include any suitable information relating to the biometric parameters, such as a message indicating that a biometric parameter of the user is greater than a threshold. The content may include images, video content, audio content, etc. that may be used present the biometric information.

In some embodiments, the sensing data may represent an amount of ambient light in the surroundings of the computing device 100. The processing device can process the sensing data and adjust a brightness of a screen of the computing device (e.g., dimming, brightening, turning on, turning off, etc.) based on the sensing data. The brightness of the screen of the computing device may be adjusted by adjusting the light produced by the semiconductor devices 115. For example, the processing device can process the sensing data to determine a value of the ambient light based on the sensing data, such as an intensity of the ambient light and/or a change in the intensities of the ambient light. The processing device can then compare the value of ambient light to one or more thresholds to adjust the brightness of the screen and/or one or more portions of the screen accordingly. In some embodiments, the processing device can decrease the brightness of the screen in response to determining that the value of ambient light is greater than a threshold (e.g., determining that the computing device is in a relatively bright environment). Similarly, the processing device can increase the brightness of the screen in response to determining that the value of ambient light is not greater than the threshold (e.g., determining that the computing device is in a relatively dark environment).

In some embodiments, the sensing data may correspond to image data of one or more objects. The image data may include data about IR radiation emitted by the objects. In such embodiments, the processing device 130 can process the sensing data and generate one or more images of the objects.

In some embodiments, the sensing data may correspond to light reflected by an object located on top of the computing device (e.g., on top of the display device). The processing device 130 can process the sensing data to determine a location of the object, a distance between the object and the computing device 100 (e.g., a distance between the object and the display device 110), a proximity of the object to the computing device 100 and/or the display device 110. For example, the processing device can determine an amount of the reflected light and can estimate a distance between the object and the display device. In some embodiments, the processing device 130 can also determine whether the object is located within a predetermined proximity of the computing device (e.g., within a threshold distance from the display device). In response to determining that the object is within the predetermined proximity of the computing device, the processing device may unlock the screen of the computing device, increase the brightness of the display device, and/or perform one or more other operations accordingly. To determine whether the object is located within the predetermined proximity of the computing device, the processing device 130 may compare the estimated distance and the threshold distance. Alternatively or additionally, the processing device can compare the amount of the reflected light and a threshold amount of light corresponding to the threshold distance.

In some embodiments, the sensing data may correspond to one or more user interactions with the computing device 100. The processing device 130 may process the sensing data to identify the one or more user interactions and may perform one or more operations based on the identified user interaction(s). Examples of the user interactions may include a gesture (e.g., a user swiping over the screen), a user selection of one or more areas of the screen, eye movements of the user, etc.

In some embodiments, the sensing data may include information that can be used to identify a user of the computing device 100. For example, the sensing data may include one or more signals representative of a fingerprint of a user (e.g., signals corresponding to temperature differences/profile/light ridges and valleys of a finger of the user). The processing device can process the sensing data to determine features of the fingerprint and compare the determined features with features of one or more known fingerprints of known users. In response to detecting a match between the determined features and known features of a known fingerprint of a known user, the processing device may determine that the user is the known user. As another example, the sensing data may include one or more signals representative of an iris of a user. The processing device can process the sensing data to perform iris recognition to identify the user. In some embodiments, the sensing data may be processed using one or more machine learning algorithms, pattern recognition algorithms, etc. to perform user identification. The processing device may process the sensing data to identify a user and may instruct the computing device to perform one or more operations (e.g., unlocking the screen) accordingly.

In some embodiments, the sensing data may include one or more signals representative of changes in blood flows of a user (e.g., a signal that is proportional to the quantity of blood flowing through the blood vessels). The processing device can process the sensing data to determine a heart rate (e.g., by determining a component of the sensing data corresponding to variations in blood volume in synchronization with the heartbeat of the user), a respiration rate (e.g., by determining a component of the sensing data corresponding to variations in blood volume with respiration of the user), etc. of the user. In some embodiments, the processing device may process the sensing data using one or more photoplethysmography (PPG) techniques.

In some embodiments, the sensing data may correspond to one or more optical signals detected by one or more sensors 120. For example, the sensing data may be and/or include the detected optical signals. As another example, the sensing data may be generated by demodulating the detected optical signals, decoding the detected optical signals, and/or processing the detected optical signals in any other suitable manner.

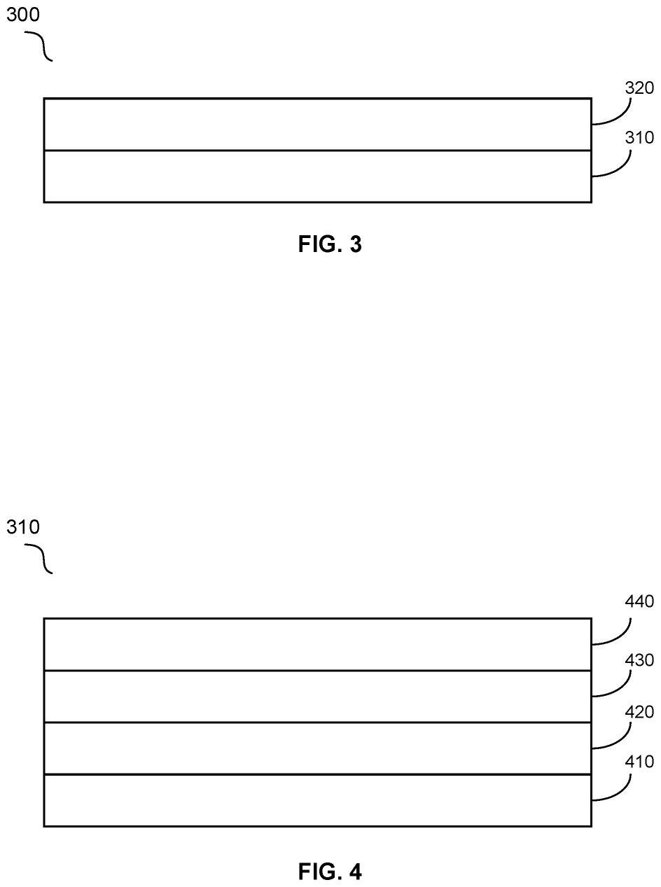

FIG. 1B is a block diagram illustrating an example of a display device in accordance with some embodiments of the present disclosure. As shown, the display device 110 may include a display area 111 comprising semiconductor devices 115. In some embodiments, one or more of the semiconductor devices 115 may have dimensions on the scale of micrometers (also referred to herein as the “micro semiconductor device”). Each semiconductor device 115 may be and/or include a flip-chip structure LED, a vertical structure LED, a lateral structure LED, etc. In some embodiments, each of the semiconductor devices 115 may include one or more semiconductor devices 300 as described in connection with FIG. 3.

In some embodiments, display device 110 may further include a display substrate 117. In one implementation, the display substrate may include a driver circuit (e.g., one or more CMOS (complementary metal-oxide-semiconductor) drivers, a TFT (Thin Film Transistor) backplane, etc. In another implementation, the display substrate does not comprise a driver circuit. The second substrate may comprise a plurality of conductive lines (e.g., rows and/or columns of conductive lines). As illustrated in FIG. 1B, the sensors 120 may be positioned beneath the display substrate 117 and the semiconductor devices 115.

Each of the sensors 120 may transmit and/or receive light and/or optical signals that may transmit through the display area 111 of the display device 110 (e.g., light and/or signals that pass through the semiconductor devices 115, the display substrate 117, a screen of the display device, etc.). For example, as illustrated in FIG. 1B, sensor 120 may transmit light 231 that can pass through the display device 110. Light 231 may reach an object 240 that is located on top of the display device 110. The object 240 is located on a surface 113 of the display device and/or the display area of the display device (e.g., a top surface of the display device). The object 240 may or may not be in direct contact with the first surface of the display. The sensors 120 are disposed beneath the surface 113 of the display device.

As another example, sensor 120 may receive light 233 that passed through the display device 110. In some embodiments, light 233 may include light reflected by an object located on top of the display device 110 (e.g., the object 240), ambient light in the surroundings of the display device 110, etc.

In some embodiments, light 231 may be and/or include an optical signal generated and/or transmitted by sensor 120 (also referred to as the “first optical signal”). Light 233 may be and/or include an optical signal transmitted from a second computing device located on top of the display device 110 (also referred to as the “second optical signal”). Each of the first optical signal and the second optical signal may be and/or include a signal carrying information and/or data using light. The second computing device may receive the optical signal 231 and process the optical signal 231 to facilitate communications with the computing device 100.

FIG. 1C depicts an example of a display area of a display in accordance with some embodiments of the present disclosure. As illustrated, display area 111 may include a plurality of semiconductor devices 115 that may produce light of various colors (e.g., red, green, blue, etc.). For example, a first set of the semiconductor devices 115a may emit light of a first color (e.g., the first plurality of micro semiconductor devices”). A second set of the semiconductor devices 115b may emit light of a second color (e.g., the second plurality of micro semiconductor devices). A third set of the semiconductor devices 115c may emit light of a third color (e.g., the “third plurality of micro semiconductor devices”). In some embodiments, the first color, the second color, and the third color may be a red color, a green color, and a blue color, respectively. A semiconductor device 115a, a semiconductor device 115b, and a semiconductor device 115c may form a pixel. As such, the semiconductor devices 115 may correspond to a plurality of pixels. Each of the pixels comprises a semiconductor device 115a emitting light of the first color, a semiconductor device 115b emitting light of the second color, and a semiconductor device 115c emitting light of the third color.

While certain numbers of semiconductor devices 115 and sensors 120 are shown in FIGS. 1B-1C, this is merely illustrative. It should be noted that the computing device 100 may include any suitable number of semiconductor devices and sensors as described herein.

FIG. 2 is a block diagram illustrating an example mechanism for implementing an under-display sensor in accordance with some embodiments of the present disclosure. As shown, sensor 120 may include a transmitter 210 and/or a receiver 220. Sensor 120 may further include any other suitable component for implementing various embodiments in accordance with the present disclosure.

Transmitter 210 may include one or more devices that can transmit signals. For example, transmitter 210 may include one or more light-emitting diodes, laser diodes, and/or any other device that may emit light that may transmit through the display device 110 and/or the display area 111. Transmitter 210 may further include one or more components that convert the light into one or more signals for transmission, such as one or more lenses, a modulator, an encoder, a signal processor, etc.

Receiver 220 may include one or more devices that can receive and/or detect light that may transmit through the display device 110 and/or the display area 111. For example, receiver 220 may include one or more photodiodes, phototransistors, and/or any other device that can detect light. Receiver 220 may further include one or more devices that can convert the detected light into an output signal (e.g., a demodulator, an analog-to-digital converter, an amplifier, etc.). The output signal may be a current signal, a voltage signal, and/or any other suitable signal that may represent the detected light.

As illustrated in FIG. 2, transmitter 210 may transmit an optical signal 231. One or more portions of optical signal 231 (e.g., light) may transmit through the display area 111 of the display device 110 and may reach a surface of an object 240. The optical signal 231 may be reflected by the surface of the object 240. The reflected light 233 may transmit through the display area 111 and may be detected by receiver 220. Receiver 220 may generate an output signal corresponding to an amount of the detected light (e.g., an intensity of the detected light, intensities of the detect light over time). As an example, the output signal may be a current signal, a voltage signal, etc. representing the amount of the detected light at a particular moment and/or over time. The output signal may be processed to determine a location of the object, the proximity of the object to the display device and/or the computing device, a surface profile of the object, motion information of the object (e.g., a speed of the object, a direction of motion of the object, a trajectory of the object, etc.), a temperature of the object, etc. The object 240 may be and/or include one or more body parts of a person (e.g., a finger, hand, face, eye, ear, etc.). The object 240 may or may not be in direct contact with the computing device and/or the display device.

Referring to FIG. 3, an example 300 of a semiconductor device in accordance with some embodiments of the present disclosure is illustrated. In some embodiments, semiconductor devices 300 may be a micro semiconductor device having dimensions on the scale of micrometers. As shown, semiconductor device 300 may include a light-emitting structure 310, a light-conversion device 320, and/or any other suitable component (e.g., one or more ohmic contacts (not shown in FIG. 3)).

The light-emitting structure 310 may include one or more layers of semiconductive materials and/or any other suitable material for producing light. For example, the light-emitting structure 310 may include one or more epitaxial layers of a group III-V material (e.g., GaN), one or more quantum well structures, etc. In some embodiments, the light-emitting structure 310 may include one or more components as described in conjunction with FIG. 4. As referred to herein, a group III material may be any material that includes an element in the boron group, such as gallium (Ga), indium (In), thallium (Tl), aluminum (Al), and boron (B). A group III-nitride material may be any nitride material containing one or more group III materials, such as gallium nitride, aluminum nitride (AlN), aluminum gallium nitride (AlGaN), indium nitride (InN), indium gallium nitride (InGaN), etc. A group V material may be any material that includes an element in the nitrogen group, such as nitrogen (N), phosphorus (P), arsenic (As), etc. A group V material may be any material that includes an element in the nitrogen group, such as nitrogen (N), phosphorus (P), arsenic (As), etc. A group III-V material may be any material that includes a group III element and a group V element, such as aluminum nitride (AlN), gallium nitride (GaN), and indium nitride (InN). The group III-V material may be a group III-nitride material in some embodiments.

The light-conversion device 320 may be and/or include quantum dots placed in one or more nanoporous structures. The quantum dots may convert light of a certain wavelength into light of one or more desired wavelengths (e.g., may convert light of a shorter wavelength to light of longer wavelength(s)). In some embodiments, the light-conversion device 320 may include one or more components as described in conjunction with FIGS. 5A-5C.

The light-conversion device 320 may or may not be in direct contact with the light-emitting structure 310. In some embodiments, the light-conversion device 320 and/or the porous structure of the light-conversion device 320 is not in direct contact with the light-emitting structure 310. For example, the light-emitting structure and the porous structure may be separated by a space. As another example, a support layer may be formed between the light-emitting structure and the light-conversion device. The support layer may comprise Al₂O₃, GaN, and/or any other suitable material.

Referring to FIG. 4, an example of the light-emitting structure 310 according to some embodiments of the present disclosure is illustrated. As shown, the light-emitting structure 310 may include a growth template 410, a first semiconductor layer 420, a second semiconductor layer 430, and a third semiconductor layer 440.

The growth template 410 may include one or more epitaxial layers of the group III-V material to be grown on the growth template 410 and/or a foreign substrate. The foreign substrate may contain any other suitable crystalline material that can be used to grow the group III-V material, such as sapphire, silicon carbide (SiC), silicon (Si), quartz, gallium arsenide (GaAs), aluminum nitride (AlN), etc. In some embodiments, the light-emitting structure 310 does not include the growth template 410.

The first semiconductor layer 420 may include one or more epitaxial layers of group III-V materials and any other suitable semiconductor material. For example, the first semiconductor layer 420 may include an epitaxial layer of a group III-V material (also referred to as the “first epitaxial layer of the group III-V material”). The group III-V material may be, for example, GaN. The first epitaxial layer of the group III-V material may include the group III-V material doped with a first conductive type impurity. The first conductive type impurity may be an n-type impurity in some embodiments. The first epitaxial layer of the group III-V material may be a Si-doped GaN layer or a Ge-doped GaN layer in some embodiments. The first semiconductor layer 420 may also include one or more epitaxial layers of the group III-V material that are not doped with any particular conductive type impurity.

The second semiconductor layer 430 may include one or more layers of semiconductor materials and/or any other suitable material for emitting light. For example, the semiconductor layer 430 may include an active layer comprising one or more quantum well structures for emitting light. Each of the quantum well structures may be and/or include a single quantum well structure (SQW) and/or a multi-quantum well (MQW) structure. Each of the quantum well structures may include one or more quantum well layers and barrier layers (not shown in FIG. 4). The quantum well layers and barrier layers may be alternately stacked on one another. The quantum well layers may comprise indium (e.g., indium gallium nitride). Each of the quantum well layers may be an undoped layer of indium gallium nitride (InGaN) that is not intentionally doped with impurities. Each of the barrier layers may be an undoped layer of the group III-V material that is not intentionally doped with impurities. A pair of a barrier layer (e.g., a GaN layer) and a quantum well layer (e.g., an InGaN layer) may be regarded as being a quantum well structure. The second semiconductor layer 430 may contain any suitable number of quantum well structures. For example, the number of the quantum well structures (e.g., the number of pairs of InGaN and GaN layers) may be 3, 4, 5, etc.

When energized, the second semiconductor layer 430 may produce light. For example, when an electrical current passes through the active layer, electrons from the first semiconductor layer 420 (e.g., an n-doped GaN layer) may combine in the active layer with holes from the third semiconductor layer 440 (e.g., a p-doped GaN layer). The combination of the electrons and the holes may generate light. In some embodiments, the second semiconductor layer 430 may produce light of a certain color (e.g., light with a certain wavelength).

The third semiconductor layer 440 may include one or more epitaxial layers of the group III-V material and/or any other suitable material. For example, the third semiconductor layer 440 can include an epitaxial layer of the group III-V material (also referred to as the “second epitaxial layer of the group III-V material”). The second doped layer of the group III-V material may be doped with a second conductive type impurity that is different from the first conductive type impurity. For example, the second conductive type impurity may be a p-type impurity. In some embodiments, the second epitaxial layer of the group III-V material may be doped with magnesium.

While certain layers of semiconductor materials are shown in FIG. 4, this is merely illustrative. For example, one or more intervening layers may or may not be disposed between two semiconductor layers of FIG. 4 (e.g., between the first semiconductor layer 420 and the second semiconductor layer 430, between the second semiconductor layer 430 and the third semiconductor layer 440, etc.). In one implementation, a surface of the first semiconductor layer 420 may directly contact with a surface of the second semiconductor layer 430. In another implementation, one or more intervening layers (not shown in FIG. 4) may be formed between the first semiconductor layer 420 and the second semiconductor layer 430. One or more intervening layers (not shown in FIG. 4) may be formed between the first semiconductor layer 420 and the growth template 410. In some embodiments, the first semiconductor layer 420 may include an undoped layer of the group III-nitride material. In some embodiments, the light-emitting structure 310 can include one or more layers of semiconductor materials and/or any other material that are formed on the third semiconductor layer 440.

FIGS. 5A, 5B, and 5C are block diagrams illustrating structures associated with an example process for fabricating a light conversion device in accordance with some embodiments of the present disclosure. The methods may include fabricating a porous structure. The porous structure may comprise one or more materials comprising pores (e.g., voids). In some embodiments, fabricating the porous structure may include forming nanoporous materials. For example, the nanoporous materials may be formed using one or more solid materials (e.g., by etching the solid material(s) to form the porous structure). Examples of the solid materials may include semiconductor materials (Si, GaN, AlN, InGaN, AlGaN, etc.), glass, plastic, metal, polymer, etc. The porous structure is also referred to herein as the “nanoporous structure.”

For example, as illustrated in FIG. 5A, a solid material 510 may be obtained for fabricating a light conversion device in accordance with the present disclosure. The solid material 510 may be fabricated into a porous structure 520 as illustrated in FIG. 5B. In some embodiments, the porous structure 520 may be fabricated by etching the solid material 510 using chemical etching and/or any other suitable etching technique. The porous structure 520 may include nanoporous materials comprising pores. As shown in FIG. 5B, the porous structure 520 may include a matrix structure 521 comprising the solid material and pores 523. Each of the pores 523 may have a nanoscale size (e.g., a size of the order of 1 nm to 1000 nm or larger). The porosity of the porous structure 520 and/or the nanomaterials (e.g., a fraction of the volume of the pores 523 over a total volume of the porous structure 520) can be in a range of 10% to 90%. In some embodiments, a diameter of a pore 523 may be equal to or greater than 10 nm. The pores 523 may be dispersed in a three-dimensional space.

As illustrated in FIG. 5C, one or more quantum dots (QDs) may be placed into the porous structure 520 to fabricate a light conversion device 530. For example, the QDs may be loaded into the porous structure 520 by infiltrating a liquid (such as toluene, polydimethylsiloxane (PDMS), Hexane, etc.) containing QDs into the porous structure 520 and/or the nanoporous materials. As the pores 523 are dispersed in a three-dimensional space, the QDs may be loaded into the three-dimensional space occupied by the pores 523. In some embodiments, the QDs may be loaded using a photolithography method, an inkjet printing method, etc.

The QDs may be and/or include semiconductor particles in nanoscale sizes (also referred to as “nanoparticles”). Each of the QDs may include any suitable semiconductor material that may be used to produce a QD for implementing light conversion devices in accordance with the present disclosure, such as one or more of ZnS, ZnSe, CdSe, InP, CdS, PbS, InP, InAs, GaAs, GaP, etc. Multiple QDs placed in the porous structure 520 may or may not include the same semiconductor material.

When excited by electricity or light, a QD may emit light of a certain wavelength and/or a range of wavelengths (also referred to as the “emission wavelength” of the QD). More particularly, for example, the QD may absorb one or more photons with a wavelength shorter than the emission wavelength of the QD. Different QDs (e.g., QDs of various shapes, sizes, and/or materials) may emit light with various wavelengths. For example, a relatively large QD may emit light with a relatively longer wavelength while a relatively smaller QD may emit light with a relatively shorter wavelength.

In some embodiments, QDs of various emission wavelengths may be placed in the porous structure and/or nanoporous materials to achieve a mixed color emission. For example, as shown in FIG. 5C, the QDs placed in the porous structure 520 may include one or more QDs 531 with a first emission wavelength (also referred to as the “first QDs”), one or more QDs 533 with a second emission wavelength (also referred to as the “second QDs”), one or more QDs 535 with a third emission wavelength (also referred to as the “third QDs”), etc. QDs 531, 533, and/or 535 may have different sizes and/or shapes to achieve different emission wavelengths. QDs 531, 533, and/or 535 may or may not contain different materials. In one implementation, QDs 531, 533, and/or 535 contain different semiconductor materials.

When excited by light 541, the first QDs may convert light 541 to light 543 with the first emission wavelength. The second QDs may convert the light 541 to light 545 with the second emission wavelength. The third QDs may convert the light 541 to light 547 with the third emission wavelength. The light 541 may be produced by any light source that is capable of producing light. Examples of the light source may include one or more light-emitting diodes, laser diodes, etc. The light source may be and/or include, for example, a light-emitting structure 310 as described herein. In some embodiments, light 541 may have a wavelength that is not longer than the first emission wavelength, the second emission wavelength, and/or the third emission wavelength. Light 543, 545, and 547 may be of different colors (e.g., red light, green light, blue light).

As shown in FIG. 5C, the first QDs, the second QDs, and the third QDs may be placed in various portions of the porous structure 520 (e.g., a first portion, a second portion, and a third portion of the porous structure 520, respectively). Each of the portions of the porous structure may include multiple layers of QDs loaded in a three-dimensional space that was formed by one or more portions of the pores 523.

In accordance with one or more aspects of the present disclosure, a light conversion device is provided. The light conversion device may include a nanoporous structure and a plurality of QDs placed in the porous structure. The porous structure may include one or more nanoporous materials. The nanoporous materials and/or the porous structure may include a matrix structure comprising one or more semiconductor materials (Si, GaN, AlN, etc.), glass, plastic, metal, polymer, etc. The nanoporous materials and/or the porous structure may further include one or more pores and/or voids.

The plurality of QDs may include QDs of various emission wavelengths, such as one or more first QDs with a first emission wavelength, one or more second QDs with a second emission wavelength, one or more third QDs with a third emission wavelength, etc. The first QDs, the second QDs, and the third QDs may or may not have the same size, shape, and/or material. In some embodiments, one or more of the first QDs may have a first size and/or a first shape. One or more of the second QDs may have a second size and/or a second shape. One or more of the third QDs may have a third size and/or a third shape. In one implementation, the first size may be different from the second size and/or the third size. In one implementation, the first shape may be different from the second shape and/or the third shape. In one implementation, one or more of the first QDs, the second QDs, and/or the third QDs may include different materials.

The light conversion device may convert light of a certain wavelength into light of one or more desired wavelengths (e.g., may convert light of a shorter wavelength to light of longer wavelength(s)). In some embodiments, the light conversion device may convert light of a first color into one or more of light of a second color, light of a third color, light of a fourth color, etc. The first color, the second color, the third color, the fourth color may correspond to a first wavelength, a second wavelength, a third wavelength, and a fourth wavelength, respectively. In some embodiments, the first color is different from the second color, the third color, and/or the fourth color. In some embodiments, the second color, the third color, and the fourth color may correspond to a red color, a green color, and a blue color, respectively. In some embodiments, the light of the first color comprises violet light.

The porous structure described herein may work as a great natural receptacle for quantum dot loading and may thus enable easy manufacturing of the light-conversion device. For example, the light-conversion device may be manufactured using a photolithography method, an inkjet printing method, etc. The porous structure may also increase internal scattering and effective pathways of light traveling in the light-conversion device. The porous structure may thus improve the light conversion efficiency of the loaded QDs.

FIG. 7 is a flowchart illustrates an example process for implementing a computing device in accordance with some embodiments of the present disclosure.

As shown, process 700 may start at block 710 where a signal that passed through a display area of a display device may be detected using one or more sensors positioned beneath the display device of the display device. The signal may include, for example, light passed through the display area of the display device, an optical signal passed through the display area of the display device, etc. The display area of the display device may include a plurality of semiconductor devices for emitting light. The one or more sensors may be positioned beneath the semiconductor devices. The display area may be and/or include display area 111 as described in connection with FIGS. 1A-1C. The sensors may be and/or include one or more sensors 120 as described in connection with FIGS. 1A-1C.

At block 720, sensing data may be generated based on the detected signal. For example, the sensors may generate one or more output signals based on the detected light and/or optical signals. The sensing data may be generated based on one or more output signals generated by the one or more sensors. For example, each of the sensors may generate an output signal indicative of an amount of the detected light at a particular moment and/or a period of time, a change in the amount of the light during a period of time, values of light and/or other input detected by the sensors over time, etc. The output signal may be and/or include an electrical signal indicative of the detected light, such as a current signal, a voltage signal, etc. The sensing data may represent an amount of ambient light in the computing device's surroundings, an amount of light reflected by an object located on top of the display device of the computing device, one or more user interactions with the computing device, information that can be used to identify a user of the computing device, information representative of changes in blood flows of a user, etc.

In some embodiments, the sensing data may correspond to one or more optical signals that passed through the display area of the computing device and detected by the sensors. Each of the optical signals may be a signal carrying information and/or data using light. For example, the sensing data may be and/or include one or more output signals generated by the one or more sensors. As another example, the sensing data may be generated by processing the output signals generated by the sensors using suitable signal processing techniques.

At block 730, the computing device may perform one or more operations based on the sensing data. Examples of the operations may include adjusting a brightness of the display device, turning on the display device, turning off the display, locking a screen of the computing device, unlocking the screen of the computing device, running an application on the computing device, presenting content using the application running on the computing device, etc.

FIG. 8 illustrates a diagrammatic representation of a machine in the example form of a computer system 800 within which a set of instructions, for causing the machine to perform any one or more of the methodologies discussed herein, may be executed. In alternative embodiments, the machine may be connected (e.g., networked) to other machines in a LAN, an intranet, an extranet, or the Internet. The machine may operate in the capacity of a server or a client device in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The computer system 800 includes a processing device 802 (e.g., processor, CPU, etc.), a main memory 804 (e.g., read-only memory (ROM), flash memory, dynamic random-access memory (DRAM) (such as synchronous DRAM (SDRAM) or DRAM (RDRAM), etc.), a static memory 806 (e.g., flash memory, static random-access memory (SRAM), etc.), and a data storage device 818, which communicate with each other via a bus 808.

Processing device 802 represents one or more general-purpose processing devices such as a microprocessor, central processing unit, or the like. More particularly, the processing device may be complex instruction set computing (CISC) microprocessor, reduced instruction set computer (RISC) microprocessor, very long instruction word (VLIW) microprocessor, or processor implementing other instruction sets, or processors implementing a combination of instruction sets. Processing device 802 may also be one or more special-purpose processing devices such as an application specific integrated circuit (ASIC), a field programmable gate array (FPGA), a digital signal processor (DSP), network processor, or the like. The processing device 802 is configured to execute the processing logic 826 for performing the operations and steps discussed herein.

The computer system 800 may further include a network interface device 822 communicably coupled to a network 864. The computer system 800 also may include a video display unit 810 (e.g., a liquid crystal display (LCD) or a cathode ray tube (CRT)), an alphanumeric input device 812 (e.g., a keyboard), a cursor control device 814 (e.g., a mouse), and a signal generation device 820 (e.g., a speaker).

The data storage device 818 may include a machine-accessible storage medium 824 on which is stored software 826 embodying any one or more of the methodologies of functions described herein. The software 826 may also reside, completely or at least partially, within the main memory 804 as instructions 826 and/or within the processing device 802 as processing logic 826 during execution thereof by the computer system 800; the main memory 804 and the processing device 802 also constituting machine-accessible storage media.

The machine-readable storage medium 824 may also be used to store instructions 826 to process 700 of FIG. 7 and other embodiments of the present disclosure, and/or a software library containing methods that call the above applications. While the machine-accessible storage medium 424 is shown in an example embodiment to be a single medium, the term “machine-accessible storage medium” should be taken to include a single medium or multiple media (e.g., a centralized or distributed database, and/or associated caches and servers) that store the one or more sets of instructions. The term “machine-accessible storage medium” shall also be taken to include any medium that is capable of storing, encoding or carrying a set of instruction for execution by the machine and that cause the machine to perform any one or more of the methodologies of the disclosure. The term “machine-accessible storage medium” shall accordingly be taken to include, but not be limited to, solid-state memories, and optical and magnetic media.

In accordance with one or more aspects of the present disclosure, methods for manufacturing a computing device are provided. The methods may include providing a display device and disposing one or more sensors beneath the display device. A display area of the display device may include a plurality of semiconductor devices emitting light. Disposing the one or more sensors beneath the display device may include disposing the one or more sensors beneath the display device.

In some embodiments, providing the display device may include providing a plurality of semiconductor devices for emitting light, wherein the plurality of semiconductor devices comprises a first plurality of semiconductor devices for emitting light of a first color, a second plurality of semiconductor devices for emitting light of a second color, and a third plurality of semiconductor devices for emitting light of a third color. In some embodiments, providing the semiconductor devices may include forming the plurality of semiconductor devices on a first substrate and transferring the plurality of semiconductor devices from the first substrate to a second substrate. In some embodiments, the first substrate may be and/or include a growth substrate for growing GaN and/or other material of the light-emitting structure. For example, the first substrate may include sapphire, silicon carbide (SiC), silicon (Si), quartz, gallium arsenide (GaAs), aluminum nitride (AlN), etc. In some embodiments, the first substrate may include a silicon Si CMOS driver wafer comprising CMOS drivers. In some embodiments, the second substrate may comprise a display substrate.

For simplicity of explanation, the methods of this disclosure are depicted and described as a series of acts. However, acts in accordance with this disclosure can occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events. Additionally, it should be appreciated that the methods disclosed in this specification are capable of being stored on an article of manufacture to facilitate transporting and transferring such methods to computing devices.

The terms “approximately,” “about,” and “substantially” may be used to mean within ±20% of a target dimension in some embodiments, within ±10% of a target dimension in some embodiments, within ±5% of a target dimension in some embodiments, and yet within ±2% in some embodiments. The terms “approximately” and “about” may include the target dimension.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. A computing device, comprising:
a display device, wherein a display area of the display device comprises a first plurality of semiconductor devices emits first light of a first color, a second plurality of semiconductor devices that emits second light of a second color, and a third plurality of semiconductor devices that emits third light of a third color, wherein the first plurality of semiconductor devices comprises a first plurality of quantum dots placed in one or more first nanoporous structures; and
a sensor positioned beneath the display area of the display device, wherein the sensor is to generate sensing data based on a signal passed through the display area of the display device, and wherein the sensor is positioned beneath the one or more first nanoporous structures.

2. The computing device of claim 1, wherein the signal comprises an optical signal, and wherein the sensor is further to detect the optical signal.

3. The computing device of claim 2, wherein the sensing data represents an amount of light reflected by an object.

4. The computing device of claim 3, wherein the object is located on a surface of the display device, and wherein the sensor is located beneath the surface of the display device.

5. The computing device of claim 1, wherein the sensing data represents an amount of ambient light in the computing device's surroundings.

6. The computing device of claim 1, wherein the computing device is further to perform one or more operations based on the sensing data, and wherein the one or more operations comprise at least one of adjusting a brightness of the display device, turning on the display device, turning off the display device, locking a screen of the computing device, unlocking the screen of the computing device, displaying media content, or performing an operation using an application running on the computing device.

7. The computing device of claim 6, wherein the computing device further comprises a processing device to generate one or more control signals that instruct the computing device to perform the one or more operations.

8. The computing device of claim 1, wherein the second plurality of semiconductor devices comprises a second plurality of quantum dots placed in one or more second nanoporous structures.

9. The computing device of claim 8, wherein the display device further comprises a display substrate, wherein the first plurality of semiconductor devices, the second plurality of semiconductor devices, and the third plurality of semiconductor devices are fabricated on the display substrate, wherein the first wherein the sensor is located beneath the display substrate.

10. The computing device of claim 1, wherein the sensor is further to transmit an optical signal that passes through the display area of the display device.

11. The computing device of claim 1, wherein the computing device is a wearable computing device, wherein the wearable computing device comprises at least one of a watch, eyeglasses, a contact lens, a head-mounted display, a virtual reality headset, an activity tracker, clothing, a wrist bands, or a skin patch.

12. The computing device of claim 1, wherein the sensor comprises at least one of an infrared (IR) sensor or an image sensor.

13. A method, comprising:
detecting, using one or more sensors positioned beneath a display device of a computing device, a signal passed through a display area of the display device, wherein the display area of the display device comprises a plurality of semiconductor devices for emitting light;
generating sensing data based on the detected signal; and
performing, by the computing device, one or more operations based on the sensing data.

14. The method of claim 13, wherein the sensing data represents an amount of ambient light in the computing device's surroundings.

15. The method of claim 13, wherein the sensing data represents an amount of light reflected by an object located on top of the display device of the computing device.

16. The method of claim 15, wherein the object is located on a surface of the display device, and wherein the one or more sensors are positioned beneath the surface of the display device.

17. The method of claim 13, wherein the signal comprises an optical signal passed through the display area of the display device.

18. The method of claim 17, further comprising: receiving, using the one or more sensors positioned beneath the display area, the optical signal passed through the display area of the display device.

19. The method of claim 13, further comprising:
transmitting, using the one or more sensors positioned beneath the display device of the computing device, an optical signal that passes through the display device of the computing device.

20. The method of claim 13, further comprising: performing, by the computing device, one or more operations based on the sensing data, wherein the one or more operations comprise at least one of adjusting a display property of the display device of the computing device, performing one or more operations using an application running on the computing device, unlocking a screen of the computing device, or locking the screen of the computing device.
